(19) United States
(12) Patent Application Publication
(10) Pub. No.: US 2011/0147705 A1
(43) Pub. Date: Jun. 23, 2011

(54) SEMICONDUCTOR LIGHT-EMITTING DEVICE WITH SILICONE PROTECTIVE LAYER

(75) Inventors: Fengyi Jiang, Jiangxi (CN); Junlin Liu, Jiang Xi (CN); Li Wang, Jiang Xi (CN)

(73) Assignee: LATTICE POWER (JIANGXI) CORPORATION, Nanchang, Jiang Xi (CN)

(21) Appl. No.: 13/059,845

(22) PCT Filed: Aug. 19, 2008
(86) PCT No.: PCT/CN2008/001496

§ 371 Date: Feb. 18, 2011

(51) Int. Cl. H01L 33/04; H01L 33/52; B82Y 99/00

(52) U.S. Cl. 257/13; 438/26; 257/E33.008; 257/E33.059; 977/949; 977/759

(57) ABSTRACT

One embodiment of the present invention provides a semiconductor light-emitting device which includes: a substrate, a first doped semiconductor layer situated above the substrate, a second doped semiconductor layer situated above the first doped semiconductor layer, a multi-quantum-well (MQW) active layer situated between the first and the second doped semiconductor layers. The device further includes a first electrode coupled to the first doped semiconductor layer, a second electrode coupled to the second doped semiconductor layer, and a silicone protective layer which substantially covers the sidewalls of the first and second doped semiconductor layers, the MQW active layer, and part of the horizontal surface of the second doped semiconductor layer which is not covered by the second electrode.

### BACKGROUND

1. Field of the Invention

The present invention relates to the design of semiconductor light-emitting devices. More specifically, the present invention relates to novel semiconductor light-emitting devices with a silicone protective layer.

2. Related Art

Solid-state lighting is expected to bring the next wave of illumination technologies. High-brightness light-emitting diodes (HB-LEDs) are emerging in an increasing number of applications, from serving as the light source for display devices to replacing light bulbs for conventional lighting. Typically, cost, efficiency, and brightness are the three foremost metrics for determining the commercial viability of LEDs.

An LED produces light from an active region, which is “sandwiched” between a positively doped layer (p-type doped layer) and a negatively doped layer (n-type doped layer). When the LED is forward-biased, the carriers, which include holes from the p-type doped layer and electrons from the n-type doped layer, recombine in the active region. In direct band-gap materials, this recombination process releases energy in the form of photons, or light, whose wavelength corresponds to the energy band-gap of the material in the active region.

Depending on the selection of the substrate and the design of the semiconductor layer stack, an LED can be formed using two configurations, namely the lateral-electrode (electrodes are positioned on the same side of the substrate) configuration and the vertical-electrode (electrodes are positioned on opposite sides of the substrate) configuration. FIGS. 1A and 1B illustrate both configurations, where FIG. 1A shows the cross-section of a typical lateral-electrode LED and FIG. 1B shows the cross-section of a typical vertical-electrode LED. Both of the LEDs shown in FIGS. 1A and 1B include a substrate layer 102, an n-type doped layer 104, a multiple-quantum-well (MQW) active layer 106, a p-type doped layer 108, a p-side electrode 110 coupled to the p-type doped layer, and an n-side electrode 112 coupled to the n-type doped layer.

The recent developments in LED fabrication technology enable the use of GaN-based III-V compound semiconductors as materials for short-wavelength LED. These GaN-based LEDs have extended the LED emission spectrum to the green, blue, and ultraviolet region. Note that in the following discussion, a “GaN material” can generally include an InxGayAl1−x−yN (0≦x≦1, 0≦y≦1) based compound, which can be a binary, ternary, or quaternary compound, such as GaN, InGaN, GaAlN, and InGaAlN.

One method for fabricating vertical-electrode LED based on GaN materials involves wafer-bonding technology. Typically, a semiconductor multilayer structure grown on a growth substrate is first bonded with another base substrate, and then the growth substrate is removed using various chemical and mechanical methods. Various types of defects, such as cracks and bubbles, often exist on the bonding interface, weakening the bond between the GaN epitaxial film and the base substrate. In addition, the GaN epitaxial film is very thin and brittle, making the subsequent fabrication processes, such as dicing, testing, and packaging, difficult. For example, during the testing process, a vacuum suction gripper is often used to lift the LED chip, and the contact force exerted by the vacuum suction gripper on the LED surface often cracks or even breaks the LED chip.

Moreover, due to the material characteristic of GaN, even for an LED fabricated without wafer bonding, the cracking and breaking of the LED chip can still be problematic during the testing and packaging process, thus decreasing the production yield.

### SUMMARY

One embodiment of the present invention provides a semiconductor light-emitting device which includes: a substrate, a first doped semiconductor layer situated above the substrate, a second doped semiconductor layer situated above the first doped semiconductor layer, a multi-quantum-well (MQW) active layer situated between the first and the second doped semiconductor layers, a first electrode coupled to the first doped semiconductor layer, a second electrode coupled to the second doped semiconductor layer, and a silicone protective layer which substantially covers the sidewalls of the first and second doped semiconductor layer, the MQW active layer, and part of the horizontal surface of the second doped semiconductor layer which is not covered by the second electrode.

In a variation on this embodiment, the silicone protective layer comprises DOW CORNING® 5351 photopatternable spin-on silicone.

In a further variation on this embodiment, the thickness of the silicone protective layer is between 1 and 100 micrometers.

In a variation on this embodiment, the substrate includes at least one of the following materials: Cu, Cr, Si, and SiC.

In a variation on this embodiment, the first doped semiconductor layer is a p-type doped semiconductor layer.

In a variation on this embodiment, the second doped semiconductor layer is an n-type doped semiconductor layer.

In a variation on this embodiment, the first and second doped semiconductor layers are grown on a substrate with a pre-defined pattern of grooves and mesas.

### BRIEF DESCRIPTION OF THE FIGURES

FIG. 1A illustrates the cross section of an exemplary lateral-electrode LED.

FIG. 1B illustrates the cross section of an exemplary vertical-electrode LED.

FIG. 2A illustrates part of a substrate with pre-patterned grooves and mesas in accordance with one embodiment of the present invention.

FIG. 2B illustrates the cross-section of the pre-patterned substrate in accordance with one embodiment of the present invention.

FIG. 3 presents a diagram illustrating the process of fabricating a vertical-electrode light-emitting device with a silicon protective layer in accordance with one embodiment of the present invention.

FIG. 4 illustrates the cross section of a lateral-electrode light-emitting device with a silicone protective layer in accordance with one embodiment of the present invention.

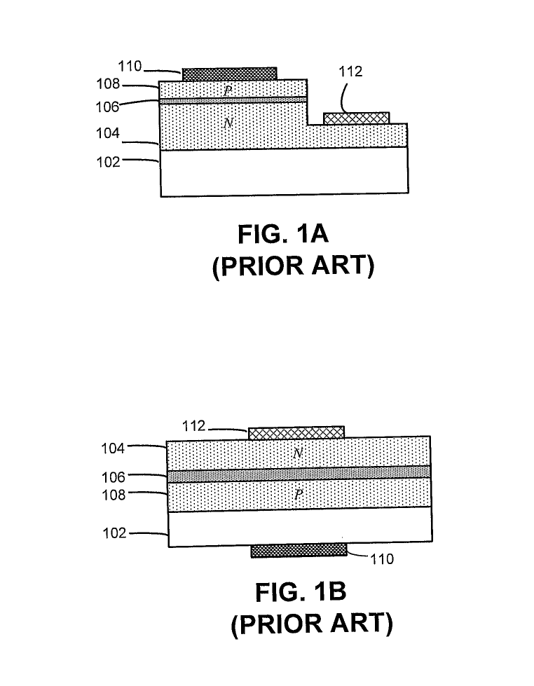

### DETAILED DESCRIPTION

The following description is presented to enable any person skilled in the art to make and use the invention, and is provided in the context of a particular application and its requirements. Various modifications to the disclosed embodiments will be readily apparent to those skilled in the art, and the general principles defined herein may be applied to other embodiments and applications without departing from the spirit and scope of the present invention. Thus, the present invention is not limited to the embodiments shown, but is to be accorded the widest scope consistent with the claims.

### Overview

Embodiments of the present invention provide a method for fabricating a light-emitting device with a protective silicone layer. After the fabrication of a light-emitting device, a layer of silicone material is deposited on the surface of the device. Note that the silicone material is highly transparent to visible light, thus causing little additional loss of light. Adding a silicone protective layer on top of the light-emitting device provides several advantages. First, due to the robust nature of the silicone material, the silicone protective layer can effectively protect the device from being damaged during subsequent testing and packaging processes. Second, the elasticity of the silicone material can effectively release the stress between the GaN film and the polyimide material traditionally used for packaging. Furthermore, the thermal conductivity and reverse breakdown characteristic of the silicone material are superior to that of the polyimide. Therefore, light-emitting devices with a silicone protective layer exhibit higher yield and better reliability compared with conventionally fabricated light-emitting devices.

Substrate Preparation

In order to grow a crack-free GaN-based III-V compound semiconductor multilayer structure on a large-area growth substrate (such as a Si wafer) to facilitate the mass production of high-quality, low-cost, short-wavelength LEDs, a growth method that pre-patterns the substrate with grooves and mesas is introduced. Pre-patterning the substrate with grooves and mesas can effectively release the stress in the multilayer structure that is caused by lattice-constant and thermal-expansion-coefficient mismatches between the substrate surface and the multilayer structure.

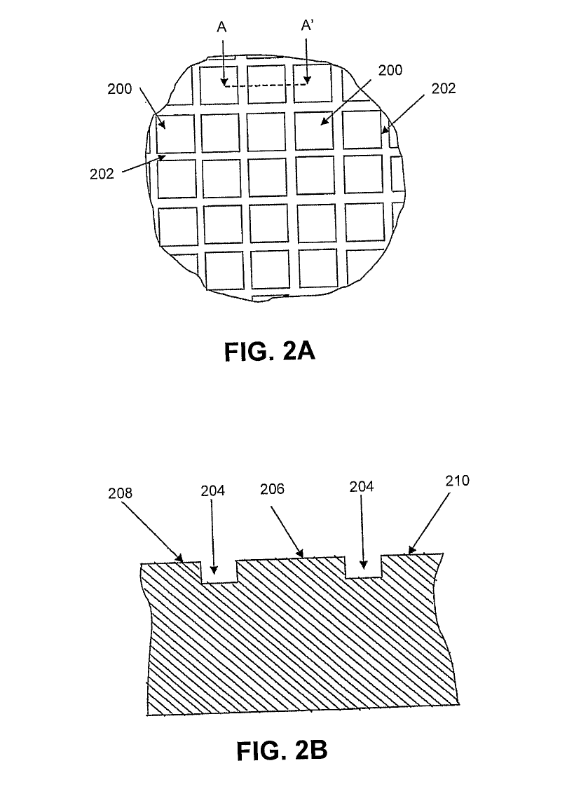

FIG. 2A illustrates a top view of part of a substrate with a pre-etched pattern using photolithographic and plasma-etching techniques in accordance with one embodiment of the present invention. Mesas 200 and grooves 202 are the result of etching. FIG. 2B more clearly illustrates the structure of mesas and grooves by showing a cross section of the pre-patterned substrate along a horizontal line A-A′ in FIG. 2A in accordance with one embodiment of the present invention. As seen in FIG. 2B, the sidewalls of grooves 204 effectively form the sidewalls of the isolated mesa structures, such as mesa 206, and partial mesas 208 and 210. Each mesa defines an independent surface area for growing a respective semiconductor device.

Note that it is possible to apply different lithographic and etching techniques to form the grooves and mesas on the semiconductor substrate. Also note that other than forming square mesas 200 as shown in FIG. 2A, alternative geometries can be formed by changing the patterns of grooves 202. Some of these alternative geometries can include, but are not limited to: triangle, rectangle, parallelogram, hexagon, circle, or other non-regular shapes.

Fabrication of a Vertical-Electrode LED

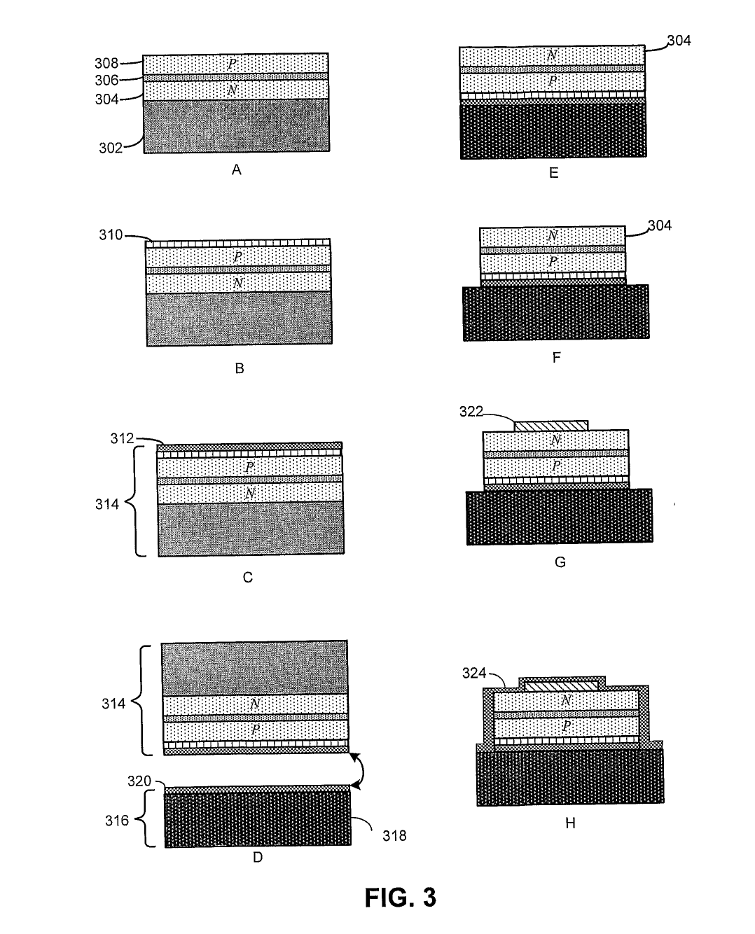

FIG. 3 presents a diagram illustrating the process of fabricating a vertical-electrode LED with a silicone protective layer in accordance with one embodiment. In operation A, after a pre-patterned growth substrate with grooves and mesas is prepared, an InGaAlN multilayer structure is formed using various growth techniques, which can include, but are not limited to metalorganic-chemical-vapor-deposition (MOCVD). The LED structure can include a substrate layer 302, which can be a Si wafer, an n-type doped semiconductor layer 304, which can be a Si doped GaN layer, an active layer 306, which can include a multi-period GaN/InGaN MQW structure, and a p-type doped semiconductor layer 308, which may be based on Mg-doped GaN. Note that it is possible to reverse the growth sequence between the p-type layer and the n-type layer, and the active layer can be optional.

In operation B, a p-side ohmic-contact layer 310 is formed on top of the p-type doped layer. In one embodiment, the p-side ohmic-contact layer can be formed by depositing a thin layer of Pt. Other metal materials can also be used to form an ohmic contact with the p-type layer.

In operation C, a bonding layer 312 is formed on top of p-side ohmic-contact layer 310. Materials that are used to form bonding layer 312 may include gold (Au).

In operation D, multilayer structure 314 is flipped upside down to bond with a supporting structure 316. In one embodiment of the present invention, supporting structure 316 includes a conductive substrate layer 318 and a bonding layer 320. Bonding layer 320 may include Au. Conductive substrate layer 318 can include at least one of the following materials: Si, GaAs, GaP, Cu, and Cr.

In operation E, growth substrate 302 is removed by, for example, a chemical etching technique or a mechanical grinding technique. The removal of growth substrate 302 exposes n-type layer 304.

In operation F, the edge of the multilayer structure is removed to reduce surface recombination centers and to ensure high material quality throughout the entire device. However, if the growth procedure can guarantee a good edge quality of the multilayer structure, then this edge removal operation can be optional.

In operation G, an ohmic-electrode 322 (n-side electrode) is formed on top of n-type layer 304. In one embodiment of the present invention, n-side electrode 322 includes Ni, Au, and/or Pt. N-side electrode 322 can be formed using, for example, an evaporation technique, such as e-beam evaporation, or a sputtering technique, such as magnetron sputtering deposition. Other deposition techniques are also possible.

In operation H, a silicone protective layer 324 is deposited on top of the device covering the n-side electrode, the exposed GaN epitaxial film, and the exposed base substrate. Various materials and techniques can be used to form protective silicone layer 324. In one embodiment of the present invention, a silicone rubber material, such as the DOW CORNING® 5331 photopatternable spin-on silicone, is used to form protective silicone layer 324. In one embodiment of the present invention, silicone protective layer 324 is spin-coated on top of the device at a rotation speed of approximately 500 to 3000 rpm for approximately 10 to 30 seconds.

In operation I, silicone protective layer 324 is photopatterned, so that part of the top surface of silicone protective layer 324 can be removed to expose n-side electrode 322. Standard photopattern processes which include exposing and developing can be used to pattern silicon protective layer 324. One embodiment of the present invention follows the procedure listed below:

1. Pre-bake the multilayer structure on a hot plate at approximately 110° C. for approximately 120 seconds.

B. Cover the multilayer structure with a photomask and expose the multilayer structure to an ultraviolet light with an approximate intensity of 1000 mJ/cm2.

2. Post-bake the multilayer structure on a hot plate at approximately 150° C. for approximately 180 seconds.

3. Submerge the multilayer structure into a negative-resist-developer (NRD) for approximately 120 seconds and then rinse the multilayer structure using a negative resist rinser for approximately 120 seconds. Note that one can also spray the NRD onto the surface of the multilayer structure to develop the photo pattern.

4. Cure the silicon protective layer at approximately 150° C. for about 120 minutes.

Depending on the adopted photopatterning processes, the thickness of the resulting silicone protective layer may be of different values. In one embodiment of the present invention, the thickness of the silicone protective layer is between 5 and 10 micrometers.

In operation J, another ohmic-electrode 326 (p-side electrode) is formed on the backside of conductive substrate 318. The material composition and the formation process of p-side electrode 326 can be similar to that of n-side electrode 322.

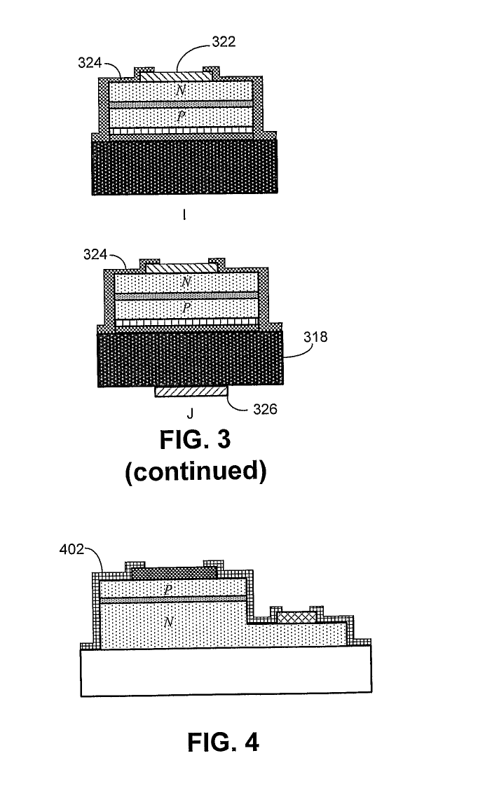

In addition to fabricating a vertical-electrode light-emitting device with silicone protective layer, a similar process can also be used to fabricate a lateral-electrode light-emitting device by placing both electrodes on one side of the device. FIG. 4 illustrates the cross section of a lateral-electrode light-emitting device with a silicone protective layer 402 on top of the device. Protective layer 402 covers the sidewalls of the p-type and n-type doped layers, the MQW active layer, part of the horizontal surface of the p-type layer which is not covered by the p-side electrode, and part of the horizontal surface of the n-type layer which is not covered by the n-side electrode.

The foregoing descriptions of embodiments of the present invention have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention. The scope of the present invention is defined by the appended claims.

What is claimed is:

1. A semiconductor light-emitting device, comprising:
a substrate;
a first doped semiconductor layer situated above the substrate;
a second doped semiconductor layer situated above the first doped semiconductor layer;
a multi-quantum-well (MQW) active layer situated between the first and the second doped semiconductor layers;
a first electrode coupled to the first doped semiconductor layer;
a second electrode coupled to the second doped semiconductor layer; and
a silicone protective layer which substantially covers the sidewalls of the first and second doped semiconductor layers, the MQW active layer, and part of the horizontal surface of the second doped semiconductor layer which is not covered by the second electrode.

2. The light-emitting device of claim 1,
wherein the silicone protective layer comprises photopatternable silicone.

3. The method of claim 2,
wherein the thickness of the silicone protective layer is between 1 and 100 micrometers.

4. The semiconductor light-emitting device of claim 1,
wherein the substrate comprises at least one of the following materials:
Cu,
Cr,
Si, and
SiC.

5. The semiconductor light-emitting device of claim 1,
wherein the first doped semiconductor layer is a p-type doped semiconductor layer.

6. The semiconductor light-emitting device of claim 1,
wherein the second doped semiconductor layer is an n-type doped semiconductor layer.

7. The semiconductor light-emitting device of claim 1,
wherein the first and second doped semiconductor layers are grown on a substrate with a pre-defined pattern of grooves and mesas.

8. A method for fabricating a semiconductor light-emitting device, the method comprising:
fabricating a multilayer semiconductor structure on a first substrate, wherein the multilayer semiconductor structure comprises a first doped semiconductor layer, an MQW active layer, and a second doped semiconductor layer;
forming a first electrode, which is coupled to the first doped semiconductor layer;
bonding the multilayer structure to a second substrate;
removing the first substrate;
forming a second electrode, which is coupled to the second doped semiconductor layer; and
forming a silicone protective layer, which substantially covers the sidewalls of the first and second doped semiconductor layers, the MQW active layer, and part of the surface of the second doped semiconductor layer which is not covered by the second electrode.

9. The method of claim 8,
wherein the silicone protective layer comprises photopatternable silicone.

10. The method of claim 9,
wherein the thickness of the silicone protective layer is between 1 and 100 micrometers.

11. The method of claim 8,
wherein the second substrate comprises at least one of the following materials:
Cu,
Cr,
Si, and
SiC.

12. The method of claim 8,
wherein the first doped semiconductor layer is a p-type doped semiconductor layer.

13. The method of claim 8,
wherein the second doped semiconductor layer is an n-type doped semiconductor layer.

14. The method of claim 8,
wherein the first substrate comprises a pre-defined pattern of grooves and mesas.

15. A semiconductor light-emitting device, comprising:
a substrate;
a first doped semiconductor layer situated above the substrate;
a second doped semiconductor layer situated above the first doped semiconductor layer;
a multi-quantum-well (MQW) active layer situated between the first and the second doped semiconductor layers;
wherein part of the first doped semiconductor layer is not covered by the second doped semiconductor layer and the MQW active layer;
a first electrode coupled to the part of the first doped semiconductor layer which is not covered by the second doped semiconductor layer and the MQW active layer;
a second electrode coupled to the second doped semiconductor layer;
wherein the first electrode and the second electrode are on the same side of the light-emitting device; and
a silicone protective layer which substantially covers the sidewalls of the first and second doped semiconductor layers, the MQW active layer, part of the horizontal surface of the first doped semiconductor layer which is not covered by the first electrode, and part of the horizontal surface of the second doped semiconductor layer which is not covered by the second electrode.

16. The light-emitting device of claim 15,
wherein the silicone protective layer comprises photopatternable silicone.

17. The light-emitting device of claim 16,
wherein the thickness of the silicone protective layer is between 1 and 100 micrometers.

18. The light emitting device of claim 15,
wherein the first doped semiconductor layer is a p-type doped semiconductor layer.

19. The light emitting device of claim 15,
wherein the second doped semiconductor layer is an n-type doped semiconductor layer.

20. The light emitting device of claim 15,
wherein the first and second doped semiconductor layers are grown on a substrate with a pre-defined pattern of grooves and mesas.
